(19) United States
(12) Patent Application Publication
(10) Pub. No.: US 2023/0221750 A1
(43) Pub. Date: Jul. 13, 2023

(54) Machinery Control Cover

(71) Applicant: Jonathan Seger, New Pairs, OH (US)

(72) Inventor: Jonathan Seger, New Pairs, OH (US)

(21) Appl. No.: 17/572,790

(22) Filed: Jan. 11, 2022

(51) Int. Cl. H05K 5/03; G05G 9/047; H05K 5/00

(52) U.S. Cl. CPC H05K 5/03; G05G 9/047; H05K 5/0017

(57) ABSTRACT

Guard The Controls is the only product of its kind that is specifically developed for control boxes housed in machinery such as: scissor lifts or boom lifts. Guard The Controls is uniquely designed with a durable thin plastic, polyurethane, or silicone material that can be easily fitted onto any and all control boxes and allows individuals to operate the equipment, while the guard is on the control panel, without restriction.

### BACKGROUND

Within the commercial industry, more often than not, companies who manage scissor lifts or boom lifts note how easy the panels on control boxes can get dirtied from paint, caulk and dirt residues. To address, it requires a deep cleaning to avoid any damage to the machinery; yet, the cleaning process can be incredibly time consuming and tedious, in addition to, the necessity to involve professional help depending on the status of the panel which can escalate the task into a costly endeavor. There have been no products available as original equipment or as an aftermarket to address this problem.

A device to simplify the cleaning process of control boxes on machinery and avoid damage. There have been no products available as original equipment or as an aftermarket to address this problem either. There exists a need for a device that is not being met by any known or disclosed device or system of present.

### SUMMARY OF THE INVENTION

The main purpose of Machinery Control Cover is to provide users with an upper control box protector that prevents water, dirt and grime from damaging the control box of a boom lift.

### BRIEF DESCRIPTION OF THE DRAWINGS

FIG. 1 is a top perspective view of the Machinery Control Cover in relation to a control panel in accordance with an embodiment of the present disclosure.

FIG. 2 is a side view of a joy stick portion of the cover including a bellows in accordance with an embodiment of the present disclosure.

FIG. 3 is a cut away view of a top to side portion of the cover including a film underneath in accordance with an embodiment of the present disclosure.

Throughout the description, similar reference numbers may be used to identify similar elements depicted in multiple embodiments. Although specific embodiments of the invention have been described and illustrated, the invention is not to be limited to the specific forms or arrangements of parts so described and illustrated. The scope of the invention is to be defined by the claims appended hereto and their equivalents.

### DETAILED DESCRIPTION

Reference will now be made to exemplary embodiments illustrated in the drawings and specific language will be used herein to describe the same. It will nevertheless be understood that no limitation of the scope of the disclosure is thereby intended. Alterations and further modifications of the inventive features illustrated herein and additional applications of the principles of the inventions as illustrated herein, which would occur to one skilled in the relevant art and having possession of this disclosure, are to be considered within the scope of the invention.

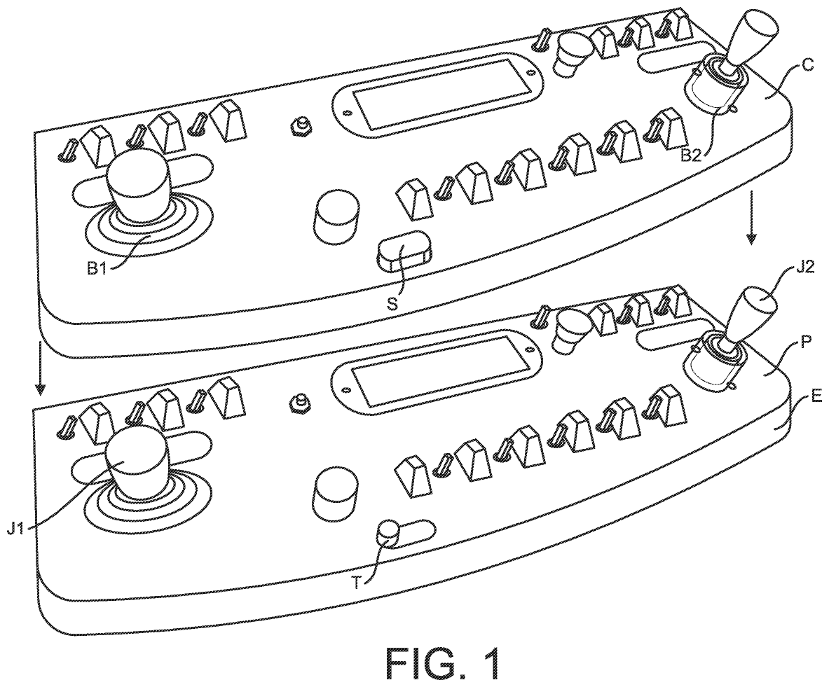

FIG. 1 is a top perspective view of Machinery Control Cover in relation to a control panel showing: fitted control box guard made of a thin material (plastic, polyurethane, or silicone) referenced as C, control box referenced as P, in accordance with an embodiment of the present disclosure. The view also includes the control panel joysticks J1 and J2 and the respective bellows covers B1 and B2. The view additionally includes the tab T of the control panel and the corresponding slot S configured to receive the tab T. The edges E include a front, back, left side and right side edge.

The present disclosed Machinery Control Cover, also known as the “Guard The Controls”, offers a modern accessory that adequately protects a control box in order to eliminate the time and money that would be otherwise associated with cleaning the control panels; thus, it significantly reduces the likelihood of box damage and the need for manual labor. Intended to complement the initial design of an average control box, Guard The Controls introduces a novel fitted safeguarding cover that protects against dirt, paint, caulk, water, or any other liquids from penetrating the control panel and ultimately serving as a support shield that does not conflict or hinder standard operation of the equipment. Guard The Controls is made of a thin plastic, polyurethane or silicone that is fitted to the control panel. This innovative, top-quality product ensures a fully operational cover that removes the need for individuals to constantly clean their control boxes and therefore saves time and allows for effective operation, at all times.

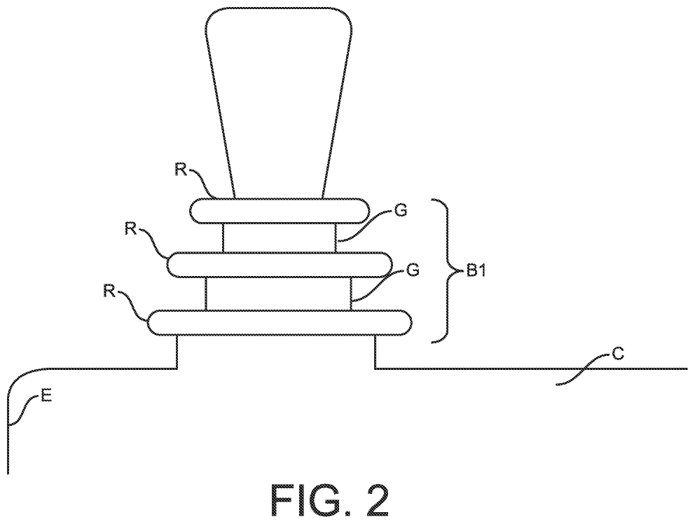

FIG. 2 is a side view of a joy stick portion of the cover including a bellows in accordance with an embodiment of the present disclosure. The view includes the bellows B1 including the concentric hollow rings R and the spacers G to cover the joystick J1. The bellows B2 is similar but comprises only a single hollow ring. The cover C continues from the edge E onward towards additional keys, screens, tabs, joysticks and buttons and toggle switches, etc.

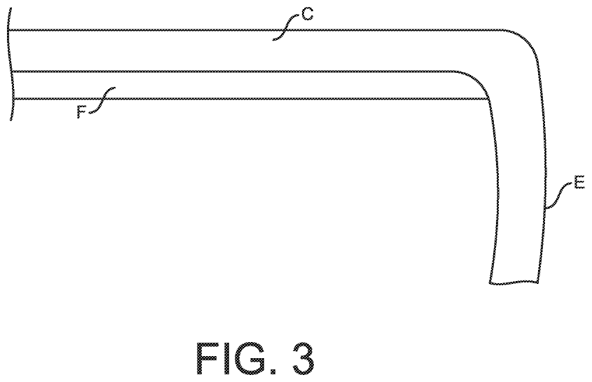

FIG. 3 is a cut away view of a top to side portion of the cover including a film underneath in accordance with an embodiment of the present disclosure. The view includes the cover C, and edge E and the film F which may or may not extend to the edge E. The film provides lubrication and a sticky film for key movement and adhesion respectively.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

What is claimed is:

1. A controls panel guard comprising:
a cover having a top, and a plurality of sides comprising a one piece molded and thin transparent material in relation to the controls panel;
a bellows on a portion of the top configured to receive a base of a joystick on the controls panel and allow a movement of the joystick therein; and
a slot on the top configured to receive a moveable tab on the controls panel and allow a movement of the tab within the slot.

2. The controls panel guard of claim 1, further comprising a lubricating film deposited on an underside of the cover to avoid a wearing of the cover on the tab and keys on the controls panel.

3. The controls panel guard of claim 1, wherein the thin transparent material is a plastic composite, a polyurethane and a silicon composite.

4. The controls panel guard of claim 1, wherein the plurality of sides comprise a front, a back, a left side and a right side similar to 5 sides of a box.

5. The controls panel guard of claim 1, wherein the bellows comprise concentric hollow rings separated by hollow spacers.

6. The controls panel guard of claim 1, wherein the cover also comprises pyramidal elevations resembling structures on the controls panel.

7. The controls panel guard of claim 1, wherein the cover further comprises parallelogram elevations resembling toggle switches on the controls panel.

8. The controls panel guard of claim 1, wherein the cover further comprises knobular elevations resembling control knobs on the controls panel.

9. The controls panel guard of claim 1, wherein the cover further comprises fully transparent portions corresponding to screens on the controls panel.

10. The controls panel guard of claim 1, further comprising a sticky film on an underside of the cover and configured to provide an attachment there between.
